(19) United States
(12) Patent Application Publication
(10) Pub. No.: US 2010/0128452 A1
(43) Pub. Date: May 27, 2010

(54) STUD, CIRCUIT BOARD DEVICE USING THE STUD, AND METHOD OF MOUNTING THE CIRCUIT BOARD DEVICE

(76) Inventor: KAZUHITO YOKOUCHI, Yamanashi (JP)

Correspondence Address: Mr. Jackson Chen, 6535 N. STATE HWY 161, IRVING, TX, 75039, US

(21) Appl. No.: 12/624,563

(22) Filed: Nov. 24, 2009

(30) Foreign Application Priority Data
Nov. 26, 2008 (JP) 2008-300848

(51) Int. Cl. H05K 1/14; H05K 1/00; H05K 3/00

(52) U.S. Cl. 361/804; 174/135; 174/250; 29/829

(57) ABSTRACT

A stud is a structure for supporting, on a printed circuit board, a mounting component such as another printed circuit board or a device. This structure is surface-mounted on the printed circuit board by soldering or press-fitting. The structure is a constituted by a columnar-shaped structure and the like. One end of the columnar-shaped structure is surface-mounted on the printed circuit board, and the other end thereof is fixed to the mounting component.

This application is based upon and claims the benefit of priority from prior Japanese Patent Application No. 2008-300848, filed Nov. 26, 2008, the entire contents of which are incorporated herein.

### TECHNICAL FIELD

The present invention relates to a stud, a circuit board device using the stud, and a method of mounting the circuit board device and, more particularly, to a stud structure for supporting a mounting component on a printed circuit board.

### BACKGROUND ART

In general, in order to achieve miniaturization of a computer apparatus, there is required, e.g., an increase in the integration degree of devices. As one of approaches for increasing the integration degree, there is known a method in which a printed circuit board is formed in a mezzanine structure to be made three-dimensional. In this method, a stud which is a structure for fixing, on a printed circuit board, a mounting component, such as another printed circuit board or a device, is used.

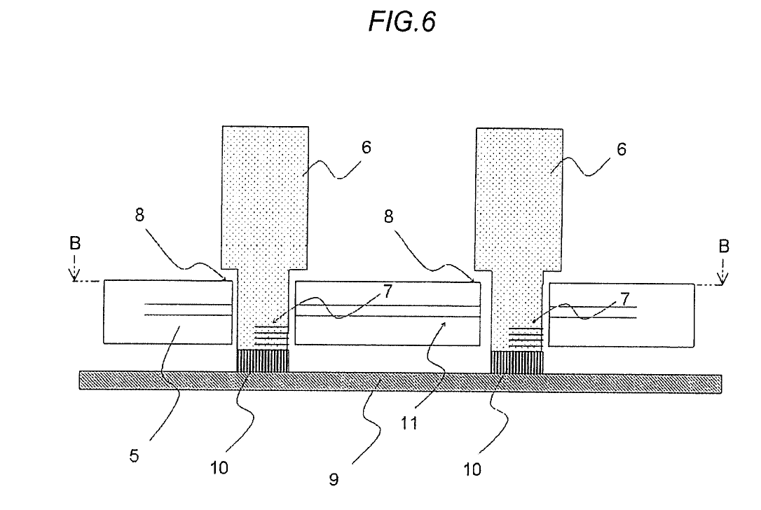

FIG. 6 shows a circuit board device according to a related art which uses the abovementioned stud. The circuit board device shown in FIG. 6 includes a plate 9, a printed circuit board 12 having a pattern wiring (electric wiring) 11 provided on the plate 9, and a plurality of stud portions each serving as a structure for mezzanine mounting a small printed circuit board (not shown) on the printed circuit board 12.

Each of the stud portions 6 includes a plate stud 10 mounted on the plate 9 and a cylindrical stud 6 which is screw fixed on the plate stud 10 through a stud/screw portion 7. A plurality of board holes 8 for stud each having a shape corresponding to the shape of the stud 6 are formed on the printed circuit board 5 so as to fix the stud 6 on the plate stud 10 though the stud/screw portion 7.

In relation to the abovementioned technique, Patent Document 1 (JP-A-2007-12951) discloses, as a supporting member for supporting a plurality of printed circuit boards arranged at a predetermined interval, a stud having one end in which a screw hole for receiving a screw for fixing one printed circuit board and the other end having a convex-shaped step portion to be inserted into a board hole of the other printed circuit board.

In the case where the method in which a printed circuit board is formed in a mezzanine structure to be made three-dimensional is adopted as an approach for increasing the integration degree in order to achieve miniaturization of a computer apparatus, it has been necessary to form a hole in the printed circuit board for fixing of the stud to the plate. Thus, the printed circuit board has a hole therein. In the case where a pattern wiring is formed on such a printed circuit board, the length of the pattern wiring is increased for the wiring to bypass the hole, with the result that the pattern wiring density becomes high. This makes signals on the pattern wiring more likely to be affected by noise to deteriorate signal quality. When the number of layers of the printed circuit board is increased so as not to allow the pattern wiring density to increase, cost of the printed circuit board becomes higher.

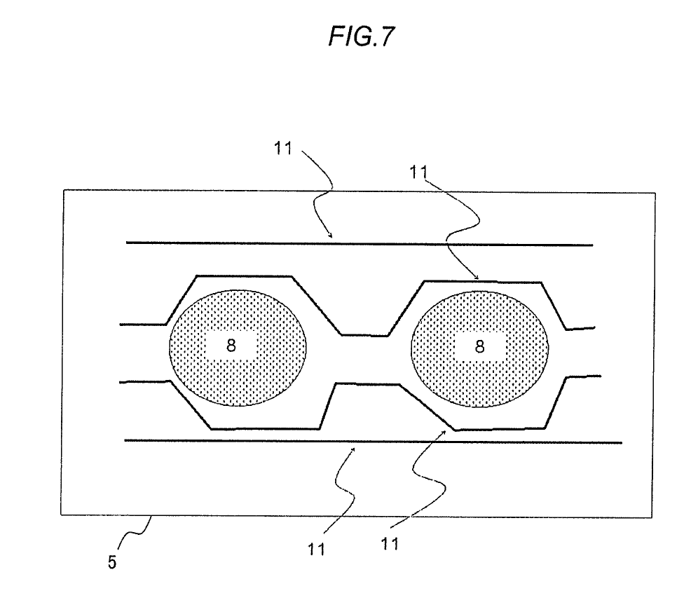

That is, in the circuit board device shown in FIG. 6, in order to fix the stud 6 to the printed circuit board 5, it has been necessary to form a board hole 8 in the printed circuit board 5 for fixing of the stud 6 to the plate 9. Thus, the pattern wiring 11 which is an electric wiring in the printed circuit board 5 is formed in a bent shape so as to bypass the base plate 8, as shown in FIG. 7. As a result, the length of the pattern wiring is accordingly increased to increase the wiring density as compared to a case where the pattern wiring 11 is linearly formed. This makes signals on the pattern wiring more likely to be affected by noise to deteriorate signal quality. Further, in order to reduce the wiring density, it is necessary to increase the number of layers of the printed circuit board 5, resulting in an increase in cost of the printed circuit board. The same problems have been encountered in the cited Patent Document 1.

### SUMMARY OF INVENTION

An exemplary object of the present invention is to provide a stud, a circuit board device using the stud, a method of mounting the circuit board device capable of solving the above problems so as to reduce the wiring density of the printed circuit board, reduce the number of layers of the printed circuit board, and allow the printed circuit board to be formed in a mezzanine structure.

According to a first aspect of the present invention, there is provided a stud which is a structure for supporting a mounting component on a printed circuit board, wherein the structure is surface-mounted on the printed circuit board.

According to a second aspect of the present invention, there is provided a circuit board device including: the stud; and a printed circuit board on which the stud has been surface-mounted.

According to a third aspect of the present invention, there is provided a method of mounting a circuit board device including: surface-mounting a stud on a printed circuit board; and mounting a mounting component on the printed circuit board through the stud.

According to the present invention, the stud is surface-mounted on the printed circuit board, so that it is possible to eliminate the need to form a hole for the stud in the printed circuit board. This allows the wiring density of the printed circuit board to be reduced to thereby reduce noise due to higher wiring density. Further, the reduction in the wiring density allows the wiring formed in another layer of the printed circuit board to be formed in the same layer, thereby reducing the number of layers of the printed circuit board. Thus, the printed circuit board can be formed in a mezzanine structure.

### BRIEF DESCRIPTION OF DRAWINGS

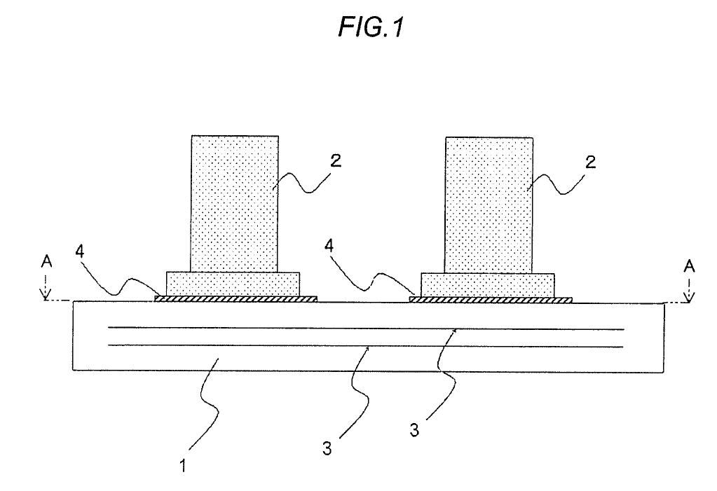

{FIG. 1} A cross-sectional view showing a stud according to an exemplary embodiment of the present invention and a circuit board device using the stud.

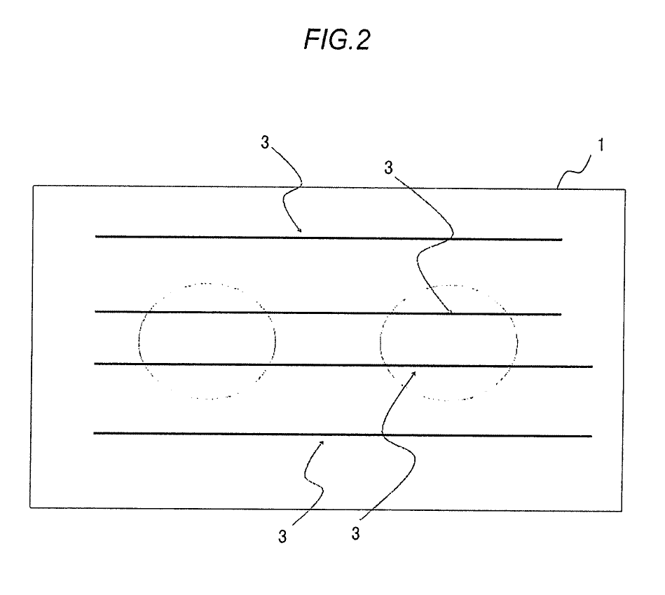

{FIG. 2} A plan view of a printed circuit board as viewed along A-A line of FIG. 1, which explains a pattern wiring image of the printed circuit board in which a board hole for stud has not been formed.

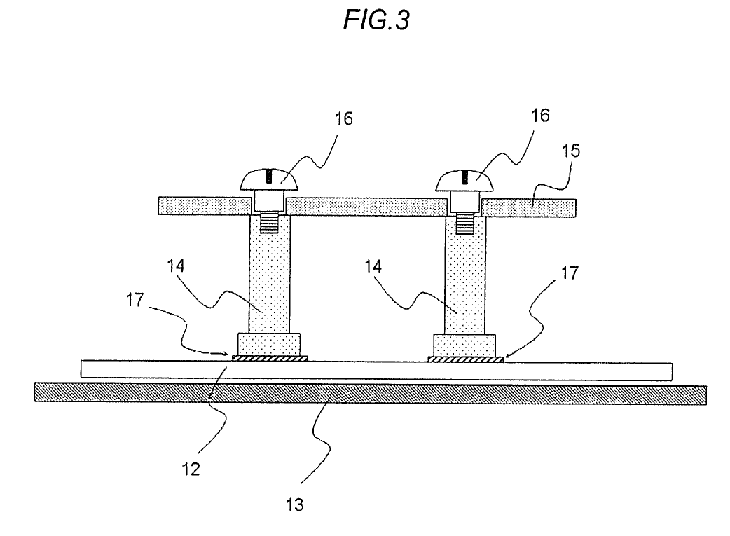

{FIG. 3} A cross-sectional view showing a stud according to a first example of the present invention and a circuit board device using the stud.

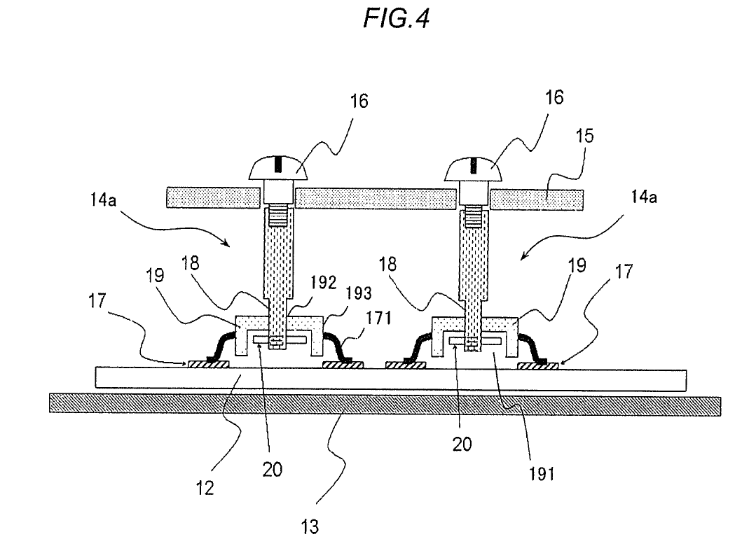

{FIG. 4} A cross-sectional view showing a stud according to a second example of the present invention and a circuit board device using the stud.

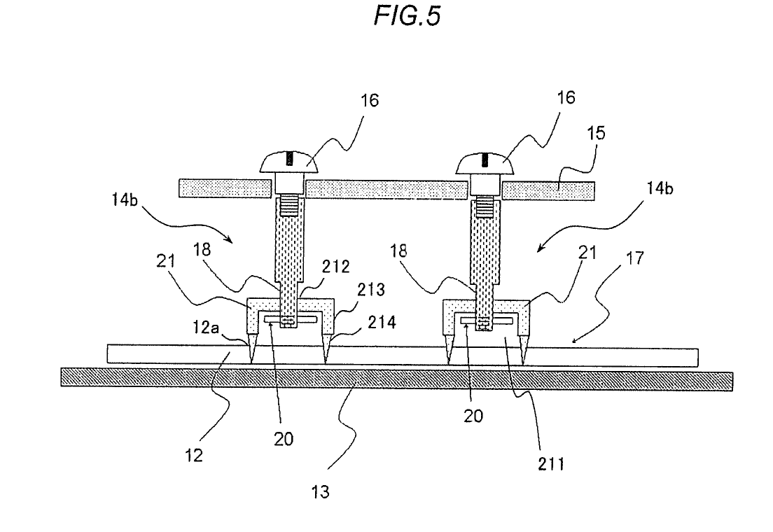

{FIG. 5} A cross-sectional view showing a stud according to a third example of the present invention and a circuit board device using the stud.

{FIG. 6} A cross-sectional view showing a circuit board device using a stud according to a related art.

{FIG. 7} A plan view of a printed circuit board as viewed along B-B line of FIG. 6, which explains a pattern wiring image of the printed circuit board in which a board hole for stud has been formed.

### DESCRIPTION OF EMBODIMENTS

An exemplary embodiment of a stud, a circuit board device using the stud, and a method of mounting the circuit board device will be described in detail below with reference to the accompanying drawings.

In a circuit board device using a stud according to the present exemplary embodiment, a stud which is a structure (columnar structure) used in screw fitting, on a printed circuit board, a mounting component, such as a small printed circuit board or a device having a smaller dimension than the printed circuit board, is formed of a component that can be surface-mounted. Hereinafter, such a stud which is a structure formed of a component that can be surface-mounted on a printed circuit board is referred to as “surface mount type stud”. In the present exemplary embodiment, the surface mount type stud is used to reduce the number of holes formed in the printed circuit board, improve wirability in the printed circuit board, and reduce the number of layers of the printed circuit board.

FIG. 1 shows a configuration of the main part of a stud according to the present exemplary embodiment and a circuit board device using the stud. The circuit board device shown in FIG. 1 includes a printed circuit board 1 having a pattern wiring (electric wiring) 3 and a plurality of surface mount type studs (corresponding to studs of the present invention) 2 which are structures for mezzanine mounting, on the printed circuit board 1, a mounting component (not shown) such as another printed circuit board or a device.

The surface mount type stud 2 has a columnar-shaped main body. One end of the main body in the axial direction is secured to a pad 4 provided on the printed circuit board 1 by soldering as in the case of other surface mount type electronic components (not shown), whereby the surface mount type stud 2 is surface-mounted on the printed circuit board 1 with the main body thereof raised. The other end of the surface mount type stud 2 in a raised state is configured to be able to be fixed to a component mezzanine mounted on the printed circuit board 1 by a fixing means (not shown) such as a locking screw.

In the present exemplary embodiment, a use of the surface mount type stud 2 eliminates the need to form a board hole for stud in the printed circuit board 1, thereby allowing the pattern wiring 3 to be drawn to the inner layer of the printed circuit board 1 without forming the board hole for stud.

That is, there is no need for the pattern wiring 3 of the printed circuit board 1 to be formed in a bent manner in order to bypass the board hole for stud, so that the pattern wiring 3 can be linearly formed on the printed circuit board 1 as shown in FIG. 2. This allows the length of the pattern wiring to be reduced to thereby reduce the wiring density of the printed circuit board 1. The reduction in the wiring density allows the wiring formed in another layer of the printed circuit board 1 to be formed in the same layer, thereby reducing the number of layers of the printed circuit board 1.

Thus, according to the present exemplary embodiment, it is possible to reduce the number of holes formed in the printed circuit board 1 to thereby significantly improve the wirability in the printed circuit board 1 of high density wiring.

Although the surface mount type stud 2 is surface-mounted on the printed circuit board 1 by soldering in the present exemplary embodiment, the present invention is not limited to this, but any connecting or fixing means can be used as long as it can surface mount the surface mount type stud 2 on the printed circuit board 1. For example, the surface mount type stud 2 can be press-fit connected to the printed circuit board 1.

Examples of the present invention will be described below.

### FIRST EXAMPLE

A first example of the present invention will be described with reference to FIG. 3.

A circuit board device according to the present example shown in FIG. 3 includes a plate 13, a printed circuit board 12 having a pattern wiring (not shown) which is disposed on the plate 13, and a plurality of surface mount type studs 14 which are columnar-shaped structures for mezzanine mounting, on the printed circuit board 12, a small printed circuit board (another printed circuit board) 15 which is a mounting component having a smaller dimension than the printed circuit board 12 by fixing thereto by means of a screw (locking screw) 16.

The surface mount type stud 14 of the present example has a columnar-shaped main body. One end of the main body in the axial direction is secured to a component pad 17 provided on the printed circuit board 12 by soldering as in the case of other surface mount type electronic components (not shown), whereby the surface mount type stud 14 is surface-mounted on the printed circuit board 12 with the main body thereof raised. In the case where the small printed circuit board 15 is mounted above the printed circuit board 12, a screw hole of the small printed circuit board 15 is made to align with the axial direction other end side leading end of the main body of the surface mount type stud 14 mounted on the printed circuit board 12, and a screw 16 is inserted into the screw hole for fixing between the small printed circuit board 15 and the leading end of the surface mount type stud 14.

According to the present example, the surface mount type stud 14 is mounted on the printed circuit board 12, so that a hole for fixing the stud need not be formed in the printed circuit board 12. As a result, it is possible to reduce the wiring density of the printed circuit board 12 and reduce noise. Further, by forming wirings in a plurality of layers in a single layer, the number of layers of the printed circuit board 12 can be reduced.

### SECOND EXAMPLE

A second example of the present invention will be described below with reference to FIG. 4.

Although the basic structure of a circuit board device according to the present example is the same as that of the circuit board device according to the first example, a further twist has been added to the structure of the surface mount type stud. The configuration is shown in FIG. 4.

A circuit board device shown in FIG. 4 includes a plate 13, a printed circuit board 12 having a pattern wiring (not shown) which is disposed on the plate 13, and a plurality of surface mount type studs 14a which are columnar-shaped structures for mezzanine mounting, on the printed circuit board 12, a small printed circuit board 15 which is a mounting component having a smaller dimension than the printed circuit board 12 by fixing thereto by means of a screw 16.

The surface mount type stud 14a according to the present example is a separate type stud constituted by a plurality of structural parts that can adjust the relative positional relationship between the printed circuit board 12 and the small printed circuit board 15. The plurality of structural parts include a stud upper portion (corresponding to a first structural part of the present invention) 18 disposed on the small printed circuit board 15 side, a stud lower portion (corresponding to a second structural part of the present invention) 19 disposed on the printed circuit board 12 side, and a stud/screw portion 20 that can adjust the position of the stud upper portion 18 with respect to the stud lower portion 19.

The stud upper portion 18 has a columnar-shaped main body. A screw hole is formed in one end of the main body. A screw 16 is inserted into the screw hole in the axial direction with the center of the screw hole aligned with the center of a screw hole of the small printed circuit board 15, whereby the stud upper portion 18 is fixed to the small printed circuit board 15. The other end of the main body of the stud upper portion 18 is inserted into a mounting hole 192 formed in the main body of the stud lower portion 19. The position of the stud upper portion 18 with respect to the stud lower portion 19 can be adjusted by the stud/screw portion 20 disposed at the insertion portion into the stud lower portion 19.

The stud lower portion 19 has a columnar-shaped main body having a larger diameter than that of the stud upper portion 18. On one side of the main body of the stud lower portion 19, a concave portion (opening portion) 191 is formed, and on the other side thereof, a mounting hole 192 having a diameter large enough to allow the other end of the main body of the stud upper portion 18 to be inserted therethrough is formed so as to penetrate the main body to reach the concave portion 191. The stud lower portion 19 has both side edge portions (opening edges) 193 of the concave portion 191, which are secured by soldering to the component pads 17 provided on the printed circuit board 12 through lead portions 171.

The stud/screw portion 20 is attached to the insertion portion into the mounting hole 192 formed in the stud lower portion 19 at the other end side of the main body of the stud upper portion 18. A screw adjustment of the stud/screw portion 20 allows the axial direction position of the stud upper portion 18 with respect to the stud lower portion 19 to be adjusted.

The stud lower portion 19 is soldered to the printed circuit board 12 and, when the small printed circuit board 15 is mounted, the stud upper portion 18 and stud/screw portion 20 are screw fixed to the stud lower portion 19. After that, the stud upper portion 18 and the small printed circuit board 15 are fixed to each other by the screw 16.

In the first example shown in FIG. 3, the surface mount type stud 14 is directly mounted on the printed circuit board 12, so that a large gradient or large mounting error in the horizontal direction occurs at the soldering portion between the surface mount type stud 14 and the component pad 17. Thus, the portion at which the small printed circuit board 15 and the surface mount type stud 14 are fixed by the screw 16 is little influenced by the mounting error of the surface mount type stud 14 when the distance between the printed circuit board 12 and the small printed circuit board 15 is small; on the other hand, when the distance between the printed circuit board 12 and the small printed circuit board 15 is large, the fixing portion between the small printed circuit board 15 and the surface mount type stud 14 is influenced by the mounting error of the surface mount type stud 14, so that a tension may be applied to the surface mount type stud 14.

In the present example, as shown in FIG. 4, the surface mount type stud 14a is divided into two parts: the stud upper portion 18 and stud lower portion 19 to provide an allowance to the surface mount type stud 14a, thereby allowing the tension applied to the surface mount type stud 14a to be absorbed. Further, the lead portion 171 commonly used as a component for an IC (Integrated Circuit) is provided to the surface mount type stud 14a so as to reduce the gradient or horizontal direction mounting error of the surface mount type stud 14a.

The shape of the stud lower portion 19 and shape of the component pad 17 at its surface mount portion in the present example are not especially limited but any shape may be used. Further, in the case where the surface mount type stud 14a according to the present example is employed, another component such as a device may be mounted above the printed circuit board 12 in place of the small printed circuit board 15.

### THIRD EXAMPLE

A third example of the present invention will be described with reference to FIG. 5.

In a circuit board device according to the third example, a further twist has been added to the structure of the surface mount type stud according to the second example. The configuration is shown in FIG. 5.

A circuit board device shown in FIG. 5 includes a plate 13, a printed circuit board 12 having a pattern wiring (not shown) which is disposed on the plate 13, and a plurality of surface mount type studs 14b which are columnar-shaped structures for mezzanine mounting, on the printed circuit board 12, a small printed circuit board 15 which is a mounting component having a smaller dimension than the printed circuit board 12 by fixing thereto by means of a screw 16.

As in the case of the second example, the surface mount type stud 14b according to the present example is a separate type stud constituted by a plurality of structural parts that can adjust the relative positional relationship between the printed circuit board 12 and the small printed circuit board 15. The plurality of structural parts include a stud upper portion (corresponding to a first structural part of the present invention) 18 disposed on the small printed circuit board 15 side, a press-fit type stud lower portion (corresponding to a second structural part of the present invention) 21 disposed on the printed circuit board 12 side, and a stud/screw portion 20 that can adjust the position of the stud upper portion 18 with respect to the press-fit type stud lower portion 21.

The stud upper portion 18 has the same configuration as that in the second example. That is, the stud upper portion 18 has a columnar-shaped main body. A screw hole is formed in one end of the main body. A screw 16 is inserted into the screw hole in the axial direction with the center of the screw hole aligned with the center of a screw hole of the small printed circuit board 15, whereby the stud upper portion 18 is fixed to the small printed circuit board 15. The other end of the main body of the stud upper portion 18 is inserted into a mounting hole 212 formed in the press-fit type stud lower portion 21. The position of the stud upper portion 18 with respect to the press-fit type stud lower portion 21 can be adjusted by the stud/screw portion 20 disposed at the insertion portion into the press-fit type stud lower portion 21.

Unlike the case of the stud lower portion 19 of the surface mount type stud 14a according to the second example, the press-fit type stud lower portion 21 is not soldered to the printed circuit board 12 but is press-fitted to the printed circuit board 12 for fixing at several points. That is, the press-fit type stud lower portion 21 has a columnar-shaped main body having a larger diameter than that of the stud upper portion 18. On one side of the main body of the press-fit type stud lower portion 21, a concave portion (opening portion) 211 is formed, and on the other side thereof, a mounting hole 212 having a diameter large enough to allow the other end of the main body of the stud upper portion 18 to be inserted therethrough is formed so as to penetrate the main body to reach the concave portion 211. Leading end portions 214 extending from both side edge portions (opening edges) 213 of the concave portion 211 are each formed to terminate in a tapered shape point. These leading end portions 214 are inserted into holes 12a formed in the printed circuit board 12 by press-fitting, whereby the press-fit type stud lower portion 21 is fitted to the printed circuit board 12.

The stud/screw portion 20 has the same configuration as that in the second example. That is, the stud/screw portion 20 is attached to the insertion portion into the mounting hole 212 formed in the press-fit type stud lower portion 21 at the other end side of the main body of the stud upper portion 18. A screw adjustment of the stud/screw portion 20 allows the axial direction position of the stud upper portion 18 with respect to the press-fit type stud lower portion 21 to be adjusted.

Even though the hole 12a for press-fitting needs to be formed in the printed circuit board 12 in the present example, the wiring density of the pattern wiring can significantly be reduced as compared to the above related art.

Further, the mounting error can be reduced in the case where the press-fit type stud lower portion 21 is employed as compared to the case where the surface mount type stud 14 according to the first example or the stud lower portion 19 according to the second example is employed. Thus, the use of the press-fit type stud lower portion 21 is effective in the case where the distance between the small printed circuit board 15 and the printed circuit board 12 is large. The surface mount type stud 14b and the small printed circuit board 15 in the present example are fixed to each other by means of the screw 16 as in the case of the first and second examples.

The shape and press-fit configuration of the press-fit type stud lower portion 21 in the present example are not especially limited but any shape or press-fit configuration may be used. Further, in the case where the surface mount type stud 14b according to the present example is employed, another component such as a device may be mounted above the printed circuit board 12 in place of the small printed circuit board 15.

Although the present invention has been described in detail with reference to the above exemplary embodiment and examples, it should be understood that the present invention is not limited to the above exemplary embodiment and examples. Various changes that those skilled in the art can understand can be made to the configuration or details of the present invention without departing from the sprit and scope of the invention.

The present invention may suitably be applied to a stud for fixing a small printed circuit board or device on a printed circuit board, a circuit board device using the stud, and a method of mounting the circuit board device.

While the invention has been particularly shown and described with reference to exemplary embodiment and examples thereof, the invention is not limited to these embodiment and examples. It will be understood by those of ordinary skill in the art that various changes in form and details may be made therein without departing from the sprit and scope of the present invention as defined by the claims.

1. A stud which is a structure for supporting a mounting component on a printed circuit board, wherein
the structure is surface-mounted on the printed circuit board.

2. The stud according to claim 1, wherein
the structure is a columnar-shaped structure having one end surface-mounted on the printed circuit board and the other end fixed to the mounting component.

3. The stud according to claim 1, wherein
the structure is surface-mounted on the printed circuit board by soldering.

4. The stud according to claim 1, wherein
the structure is surface-mounted on the printed circuit board by press-fitting.

5. The stud according to claim 1, wherein
the structure is constituted by a plurality of structural parts that can adjust the relative positional relationship between the printed circuit board and the mounting component.

6. The stud according to claim 5, wherein
the plurality of structural parts include
a first structural part disposed on the printed circuit board side and
a second structural part disposed on the mounting component side, and
the first and second structural parts are connected to each other such that the positions thereof can be adjusted.

7. The stud according to claim 6, wherein
the first and second structural parts are connected to each other such that the positions thereof can be adjusted by means of a screw.

8. The stud according to claim 6, wherein
the first structural part is fixed on the printed circuit board by soldering.

9. The stud according to claim 6, wherein
the first structural part is fixed on the printed circuit board by press-fitting.

10. The stud according to claim 6, wherein
the second structural part is fixed to the mounting component by screw fastening.

11. A circuit board device comprising:
a stud as claimed in claim 1; and
a printed circuit board on which the stud has been surface-mounted.

12. The circuit board device according to claim 11,
further comprising a mounting component supported on the printed circuit board by the stud.

13. The circuit board device according to claim 12, wherein
the mounting component is another printed circuit board or a device.

14. A method of mounting a circuit board device comprising:
surface mounting a stud on a printed circuit board; and
mounting a mounting component on the printed circuit board through the stud.

15. The mounting method according to claim 14, wherein
the stud is surface-mounted on the printed circuit board by soldering.

16. The mounting method according to claim 15, wherein
the stud is surface-mounted on the printed circuit board by press-fitting.
